(19) United States
(12) Patent Application Publication
(10) Pub. No.: US 2007/0120208 A1
(43) Pub. Date: May 31, 2007

(54) Wide bandgap semiconductor based field effect transistors

(75) Inventor: Chayan Mitra, Bangalore (IN)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/288,511

(22) Filed: Nov. 28, 2005

(51) Int. Cl. H01L 29/84

(52) U.S. Cl. 257/417

(57) ABSTRACT

A field effect transistor includes a wide bandgap semiconductor substrate including a source region, a drain region, and an intermediate region situated between the source region and the drain region. The intermediate region forms a gate channel of the field effect transistor upon application of a stimulus to the intermediate region.

### BACKGROUND

The invention relates generally to field effect transistors and in particular to wide bandgap semiconductor based field effect transistors.

Electronic devices based on wide bandgap semiconductors offer superior high voltage, high power, high temperature, and high frequency operation. A number of power devices use the wide bandgap, high power and harsh environment tolerance of gallium nitride (GaN). Heterostructures based on aluminum gallium nitride (AlGaN) and GaN provide a great deal of flexibility for novel device design and are used for many power device applications.

Most GaN based devices are grown heteroepitaxially on foreign substrates such as sapphire and silicon carbide (SiC). Mismatches in lattice constants and thermal expansion coefficients between the epilayers and the substrates manifest as a high density of threading dislocations and a large residual strain, which may be detrimental to the performance of high power electronic devices.

A field effect transistor (FET) includes a drain, a source, and a gate. The gate is separated from the source and drain by a dielectric layer. On application of a voltage or an electric field on the gate, the source to drain current may be controlled. High temperature application of a FET may result in dielectric breakdown at the dielectric/semiconductor interface resulting in gate leakage currents that may adversely affect the performance of the FET. Another limitation in high power applications sometimes results from ohmic structures such as metal/semiconductor junctions. At high temperatures, device performance may not be reproducible due to inconsistency in the behavior of the metal/semiconductor junctions.

Therefore, there is a need to address these issues to enhance the performance of field effect transistors. It would be desirable to provide new structures and methods related to fabrication of wide bandgap semiconductor based field effect transistors.

### BRIEF DESCRIPTION

In accordance with one embodiment of the invention, a wide bandgap semiconductor based field effect transistor (FET) is provided. The FET includes a source region, a drain region, and an intermediate region situated between the source region and the drain region. The intermediate region forms a gate channel of the FET on application of a stimulus to the intermediate region.

In another embodiment of the invention, a FET with a GaN substrate is provided. The FET includes a source region, a drain region, and an intermediate region situated between the source region and the drain region. The intermediate region forms a gate channel of the FET on application of a stimulus to the intermediate region.

In yet another embodiment of the invention, a FET with a GaN substrate is provided. The FET includes a source region, a drain region, and an intermediate region situated between the source region and the drain region. The intermediate region includes a graded layer that transitions from GaN towards AlGaN or aluminum nitride at a top surface of the graded layer.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic representation of a field effect transistor in accordance with an embodiment of the invention;

FIG. 2 is a schematic representation of another field effect transistor in one embodiment of the invention;

FIG. 3-6 depicts fabrication of a FET in accordance with an embodiment; and

FIG. 7 is a schematic representation of gate channel formation on application of stimulus.

### DETAILED DESCRIPTION

In accordance with an embodiment of the invention, a wide bandgap semiconductor based field effect transistor (FET) is provided. The FET includes a source region, a drain region, and an intermediate region situated between the source region and the drain region. A gate channel forms on the intermediate region of the FET on application of a stimulus to the intermediate region.

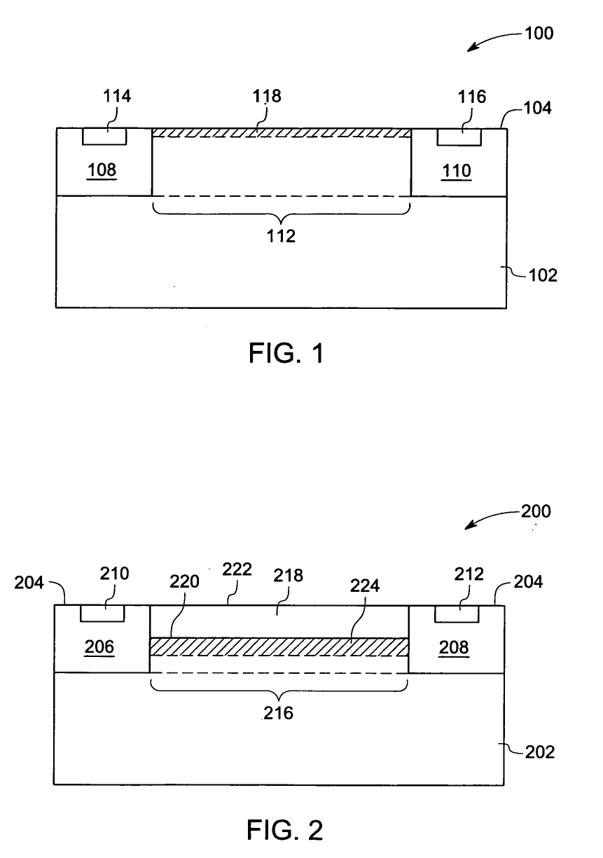

FIG. 1 is a cross-sectional view of a FET in accordance with one embodiment. The FET 100 includes a wide bandgap semiconductor substrate 102 having a top surface 104. Wide bandgap semiconductors include semiconductors with a bandgap energy of greater than about 2 eV. Non-limiting examples of wide bandgap semiconductor substrates that can be used include gallium nitride (GaN), silicon carbide (SiC), and aluminum nitride (AlN).

A source region 108 and a drain region 110 are patterned within the substrate 102. In the illustrated embodiment, the source region 108 and the drain region 110 are in contact with the top surface 104. The source region 108 and the drain region 110 are n doped, and the concentration of n doping, in this example, is in a range from about 10¹⁷ cm⁻³ to about 10¹⁸ cm⁻³.

The region between the source region 108 and the drain region 110 is marked as intermediate region 112. In the illustrated example, the intermediate region 112 is in contact with the top surface 104 of the GaN substrate 102.

A source contact 114 and a drain contact 116 are provided on the source region 108 and the drain region 110 respectively. In one embodiment, the source contact 114 and the drain contact 116 are made of metals such as platinum, nickel, silver, or gold, for example.

GaN, being polar, lacks inversion symmetry and exhibits spontaneous polarization that manifests itself as a polarization charge. Due to the polarization charge, a spontaneous electric field is formed which results in an increased sheet carrier charge density. The polarization charge may be further induced by application of stimulus. The further induced polarization is referred to herein as piezoelectric polarization. The total polarization on GaN is a sum of spontaneous polarization and piezoelectric polarization. Embodiments of the present invention make use of the piezoelectric polarization to form a field effect transistor, and use the total polarization to maximize the flow of charge from a source to drain of the FET. Although polarization is expected to be highest for GaN, polarization also occurs in other wide bandgap materials such as SiC and AlN.

On application of a stimulus on the intermediate region 112, polarization charge builds up on the intermediate region 112 to form a channel layer 118 with high charge density. The polarization charge build-up and the resultant flow of charge or current from source region 108 to drain region 110 may be varied by controlling the stimulus.

The current from source region to drain region is a function of the stimulus on the intermediate region. This is similar in behavior to a conventional FET, wherein on applying a bias across the gate, the source to drain current may be controlled. The channel layer is otherwise termed as a gate channel since it performs the function of a gate channel of a conventional FET.

As compared to a conventional FET, the FET illustrated in FIG. 1 does not require a gate contact. As mentioned earlier, during high temperature operation, the gate contact or the semiconductor/metal contact or interface has the potential to behave inconsistently and cause the FET performance to not be reproducible.

The current across the source to drain is measured in terms of conductance which is a function of concentration and mobility of charge carriers of the gate channel. The conductance depends on the amount of stimulus and also on the distance between the source region and the drain region. The distance between the source region and the drain region may be adjusted to maximize conductance. The source region 108 and the drain region 110 are typically separated by a distance ranging from about 0.5 microns to about 2 microns. In a more specific embodiment, the distance between the source region and the drain region is in a range from about 1 micron to about 1.5 microns. In a still more specific embodiment, the distance between the source region and the drain region is about 1 micron.

In FIG. 1, the gate channel 118 extends along the top surface 104 and is situated between the source region 108 and the drain region 110. In the illustrated example, the thickness of the gate channel is about 200 angstroms (Å). In certain embodiments, the thickness of the gate channel is less than about 200 Å.

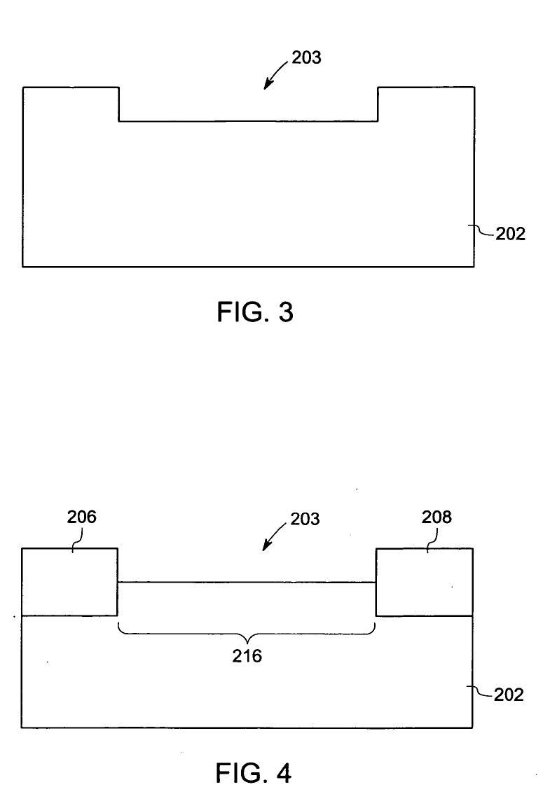

FIG. 2 is a cross-sectional view of a FET in accordance with another embodiment. The FET 200 in FIG. 2 includes a GaN substrate 202 having a top surface 204. A source region 206 and a drain region 208 are patterned within the substrate 202 and in contact with the top surface 204. The source region 206 and the drain region 208 are n doped. The source region 206 and the drain region 208 further include a source contact 210 and a drain contact 212, respectively.

The area between the source region 206 and the drain region 208, as shown in the illustrated example, is denoted as intermediate region 216. A graded layer 218 is epitaxially grown over the GaN substrate 202 and forms part of the intermediate region 216. The graded layer transitions from GaN at a bottom surface 220 of the graded layer to AlGaN or AlN at the top surface 222 of the graded layer. The amount of aluminum in the AlGaN may be varied to obtain the graded layer. In one example, AlGaN having a formula of Alₓ Ga₁₋ₓN, the (x) may take a value from about 0 at the GaN substrate to about 1 at the top surface of the graded layer. In certain embodiments, the graded layer includes a layered structure with a number of layers of differing aluminum concentration. In such embodiments, the topmost layer at the top surface of the graded layer in one example is AlN.

The lattice constant of the AlGaN is about 3.110 Å while the lattice constant of GaN is about 3.189 Å. The difference in the lattice constants between the two is about 2.4% and results in a strain at the interface between the GaN substrate and the graded layer 218. A stimulus on the GaN induces piezoelectric polarization below an interface between the GaN/AlGaN in addition to the inherent spontaneous polarization of GaN and AlGaN, as mentioned earlier.

Upon applying a stimulus on the intermediate region, a gate channel 224 is formed. In the illustrated example, the gate channel 224 forms in the intermediate region 216, below an interface between the GaN substrate and the graded layer. The graded layer shifts the sheet carrier charge density from the top surface 222 to the region below the interface of the intermediate region and the graded layer.

The thickness of the gate channel may be controlled by varying the concentration of aluminum in the AlGaN. In the shown example, thickness of the gate channel is about 500 Å. In certain embodiments, thickness of the gate channel is greater than about 500 Å.

The FETs as described above are operable at high temperature due to the presence of wide bandgap semiconductor and also due to the absence of gate metal contacts. In one example, the FET is operable at temperatures in excess of 200 degree Celsius. In certain embodiments, the operating temperature is about 700 degree Celsius.

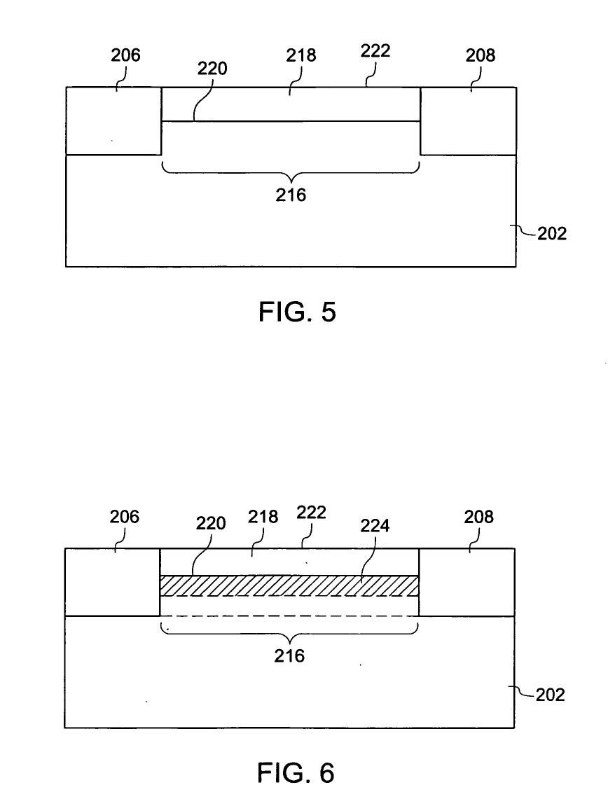

FIGS. 3-6 illustrate fabrication stages of the FET 200 in accordance with an embodiment. FIG. 3 depicts a GaN substrate 202 with a trough 203. A source region 206 and a drain region 208 are patterned within the substrate 202, as shown in FIG. 4. The patterning may optionally include techniques such as masking and etching followed by ion implantation. The source region 206 and the drain region 208 are n-doped with typical concentration in a range from about 10¹⁷ cm⁻³ to about 10¹⁸ cm⁻³. The area between the source region 208 and the drain region 210 is the intermediate region 216.

A graded layer 218 is epitaxially grown in the trough 203 of the GaN substrate 202, as shown in FIG. 5. The graded layer transitions from GaN at the bottom surface 220 of the graded layer to AlGaN or AIN at the top surface 222. The graded layer may be formed using a metal organic chemical vapor deposition (MOCVD) technique, for example. The graded layer forms part of the intermediate region 216. FIG. 6 depicts a gate channel formation below an interface of the GaN substrate and the graded layer on application of strain to the intermediate region 216. The thickness of the gate channel 224 may be varied by adjusting the concentration of aluminum.

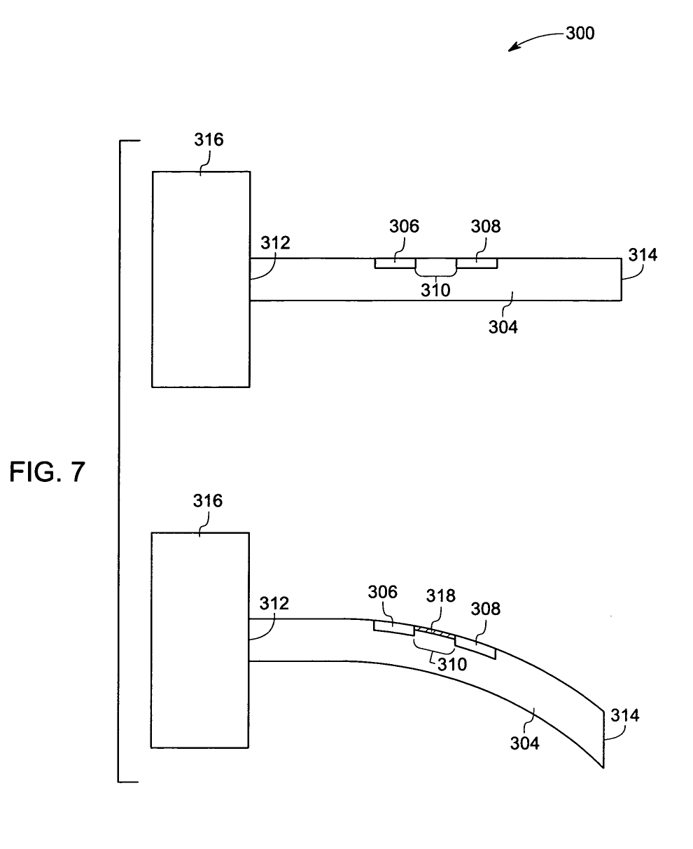

Non-limiting examples of stimulus includes pressure, strain, and combinations of pressure and strain. In one embodiment as shown in FIG. 7; stimulus is applied on the GaN substrate. In this example, a FET such as shown in FIG. 1 is adhered to a rigid block to form a cantilever structure. The top part of FIG. 7 depicts a basic FET 300 attached to a rigid block. The FET 300 includes a GaN substrate 304, a source region 306, and a drain region 308. The area between the source region 306 and the drain region 308 is intermediate region 310. The left edge 312 of the substrate 304 is attached to a rigid block 316.

As shown at the bottom of FIG. 7, a stimulus is applied on the right edge 314 of the substrate by applying force. Upon application of force, a thin channel layer 318 forms in the intermediate region 310 situated between the source region 306 and the drain region 308. In one example, the bending of the substrate results in strain. In another embodiment, direct pressure or force is exerted on the intermediate region to form the gate channel. The concentration of charge carriers in the gate channel is proportional to the stimulus applied as well as on length of the substrate 304. For a constant applied force, the charge carrier density is linearly dependent on the length of the substrate. In an exemplary example, for a constant force of about 0.6 Newton, the typical charge carrier density generated is about 6×10⁻⁴ Coulomb per millimeter square (C/mm²). In certain embodiments, the concentration of charge carriers is in a range from about 1×10⁻⁴ C/mm² to about 7×10⁴ C/mm². for a length from about 0.5 millimeters to about 10 millimeters. The thickness as well as the position of the channel layer may be varied by incorporating a graded layer in the intermediate region as mentioned with reference to FIG. 2.

The FETs that are described herein are operable either as traditional FETs or as pressure or strain sensors. Because the source to drain current is a function of the stimulus applied this may be utilized to build a strain or pressure sensor. In one embodiment, the conductance between the source and the drain region is used to measure the strain or pressure applied on the GaN substrate.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A field effect transistor comprising,
a wide bandgap semiconductor substrate comprising a source region, a drain region, and an intermediate region situated between the source region and the drain region,
wherein the intermediate region forms a gate channel of the field effect transistor upon application of a stimulus to the intermediate region.

2. The field effect transistor of claim 1, wherein the wide bandgap semiconductor comprises gallium nitride, aluminum nitride, or silicon carbide.

3. The field effect transistor of claim 1, wherein the source region and the drain region are n doped.

4. The field effect transistor of claim 1, wherein the source region and the drain region are separated by a distance from about 0.5 microns to about 2 microns.

5. The field effect transistor of claim 4, wherein the source region and the drain region are separated by a distance from about 1 micron to about 1.5 microns.

6. The field effect transistor of claim 1, wherein the stimulus comprises pressure, strain, or combinations thereof.

7. The field effect transistor of claim 1, wherein a thickness of the gate channel is less than about 200 Å.

8. The field effect transistor of claim 1, wherein the field effect transistor comprises a strain sensor or a pressure sensor.

9. The field effect transistor of claim 1, wherein the field effect transistor is operable at a temperature in excess of about 200 degree Celsius.

10. The field effect transistor of claim 1, wherein the wide bandgap semiconductor comprises gallium nitride, wherein the intermediate region comprises a graded layer transitioning from gallium nitride at the substrate to aluminum gallium nitride or aluminum nitride at a top surface of the graded layer.

11. A field effect transistor comprising,
a gallium nitride substrate comprising a source region, a drain region, and an intermediate region situated between the source region and the drain region,
wherein the intermediate region forms a gate channel of the field effect transistor upon application of a stimulus to the intermediate region.

12. The field effect transistor of claim 11, wherein the stimulus comprises pressure, strain or combinations thereof.

13. The field effect transistor of claim 11, wherein a thickness of the gate channel is less than about 200 Å.

14. The field effect transistor of claim 11, wherein the field effect transistor comprises a strain sensor or a pressure sensor.

15. The field effect transistor of claim 11, wherein the intermediate region comprises a graded layer transitioning from gallium nitride at the substrate to aluminum gallium nitride or aluminum nitride at a top surface of the graded layer.

16. A field effect transistor comprising,
a gallium nitride substrate and comprising a source region, a drain region, and an intermediate region situated between the source region and the drain region,
wherein the intermediate region comprises a graded layer transitioning from gallium nitride at the substrate to aluminum gallium nitride or aluminum nitride at a top surface of the graded layer,
wherein the intermediate region forms a gate channel of the field effect transistor upon application of a stimulus to the intermediate region.

17. The field effect transistor of claim 16, wherein the source region and the drain region are n doped.

18. The field effect transistor of claim 16, wherein the stimulus comprises pressure, strain, or combinations thereof.

19. The field effect transistor of claim 16, wherein a thickness of the gate channel is greater than about 500 Å.

20. The field effect transistor of claim 16, wherein the field effect transistor comprises a strain sensor or a pressure sensor.
